(19) United States
(12) Patent Application Publication
(10) Pub. No.: US 2025/0129480 A1
(43) Pub. Date: Apr. 24, 2025

(54) FILM FORMING DEVICE AND FILM FORMING METHOD

(71) Applicant: NISSIN ELECTRIC CO., LTD., Kyoto (JP)

(72) Inventors: Satoru NAGAMACHI, Kyoto (JP); Ryota ANDO, Kyoto (JP); Natsuo TATSUMI, Kyoto (JP); Yasunori ANDO, Kyoto (JP)

(73) Assignee: NISSIN ELECTRIC CO., LTD., Kyoto (JP)

(21) Appl. No.: 18/833,913

(22) PCT Filed: Apr. 27, 2023
(86) PCT No.: PCT/JP2023/016688

§ 371 Date: Jul. 28, 2024

(30) Foreign Application Priority Data
May 10, 2022 (JP) 2022-077363

(51) Int. Cl. C23C 16/507; C23C 16/27; C23C 16/52

(52) U.S. Cl. CPC C23C 16/507; C23C 16/272; C23C 16/52

(57) ABSTRACT

This film forming device includes: a vacuum container in which a substrate is disposed; an antenna that generates inductively coupled plasma in the vacuum container and that includes a conductor element and a capacitor element that are electrically connected to each other in series; a high-frequency power supply that supplies high-frequency current to the antenna; and a gas supply mechanism that supplies raw material gas containing C, H, and O into the vacuum container. A carbon-based thin film is formed on the substrate in the vacuum container by a plasma CVD method using the inductively coupled plasma generated in the vacuum container by applying the high-frequency current to the antenna.

### TECHNICAL FIELD

The present invention relates to a film forming device and a film forming method that form a carbon-based thin film according to a plasma CVD method.

### RELATED ART

Conventionally, film forming devices that synthesize a carbon-based thin film such as diamond using a CVD method are known to include a filament CVD device, a microwave resonator-type plasma CVD device, a microwave surface wave plasma CVD device, a high-frequency inductively coupled (RF-ICP) plasma CVD device using coil-shaped electrodes, etc. (e.g., Patent Document 1). Further, in the RF plasma type, a straight line-shaped antenna type ICP plasma CVD device is also known.

The filament CVD device is configured to include a metal wire having a high melting point provided above a substrate forming diamond, and decompose a raw material gas by thermoelectrons emitted upon heating the metal wire to synthesize diamond. Further, in a plasma CVD device using microwaves or a plasma CVD device using high frequencies, a plasma containing a raw material gas is generated by an applied high-frequency current, and diamond is synthesized by an activated gas. It is known that in these CVD devices, active atomic hydrogen is mainly generated in the plasma, and by an action thereof, non-diamond components of sp1 bonds or sp2 bonds are removed and diamond components of sp3 bonds can be mainly grown.

### RELATED ART DOCUMENT

### Patent Document

Patent Document 1: Japanese Patent Application Laid-Open No. 2003-55087

### SUMMARY OF INVENTION

### Problem to Be Solved by Invention

In the case of synthesizing diamond using the plasma CVD devices as described above, due to limitations on device configurations, diamond can be synthesized only in a small area. For example, even if the filament is stretched long, the filament cannot withstand its own weight and breaks during heating. Further, although microwaves of 2.45 GHz, 915 MHz, etc. are used, the plasma size cannot be increased due to the issue of the resonance wavelength.

Further, in the case of high-frequency inductive coupling using coil-shaped electrodes, plasma inhomogeneity occurs due to the size of the coil. Further, although element ratios between C (carbon), H (hydrogen), and O (oxygen) in the raw material gas is important, conventional CVD methods have an issue that diamond can only be synthesized with a raw material gas having a very narrow composition range. Specifically, as shown in a Bachmann C—H—O diagram of FIG. 9 showing element ratios between C, H, and O, diamond can only be synthesized in ranges of 0.8≤H/(H+C) and O/(O+H)≤0.1. Further, with straight line-shaped antennas, it has been difficult to generate a high-density plasma, and diamond could not be synthesized.

The present invention has been made to solve the above problems, and a main objective thereof is to make it possible to form a carbon-based thin film with a raw material gas having a wide composition range and form a film in a large area in a film forming device that forms a carbon-based thin film such as diamond according to a CVD method.

### Means for Solving Problem

That is, a film forming device according to the present invention includes a vacuum container, an antenna, a high-frequency power supply, and a gas supply mechanism. A substrate is disposed in the vacuum container. The antenna generates an inductively coupled plasma in the vacuum container and includes a conductor element and a capacitor element electrically connected in series with each other. The high-frequency power supply supplies a high-frequency current to the antenna. The gas supply mechanism supplies a raw material gas containing C, H, and O into the vacuum container. A carbon-based thin film is formed on the substrate in the vacuum container according to a plasma CVD method using the inductively coupled plasma that is generated in the vacuum container by passing the high-frequency current through the antenna.

With such a configuration, by using an inductively coupled plasma generated by a high-frequency induced electric field, it becomes possible to decompose CO₂ or the like, which is a molecule with a high binding energy contained in the raw material gas, over a wide range, and generation of oxygen-containing radicals can be promoted. Further, since the inductively coupled plasma is generated by a so-called LC antenna having a conductor element serving as an inductor and a capacitor element serving as a capacitor, activation can be performed for a long time even if the raw material gas has a gas composition containing a large amount of oxygen. Alternatively, the inductively coupled plasma may also be generated by a straight line-shaped antenna in which a plurality of straight line-shaped conductor elements serving as inductors and a capacitor element serving as a capacitor therebetween are connected in series. Herein, the capacitor element serving as a capacitor refers to a capacitor element different from a matching box. Thus, a carbon-based thin film such as diamond can be formed with a raw material gas having a wide composition range that cannot be realized according to a method using a conventional CVD device, and a carbon-based thin film having a large area can be formed compared to a conventional plasma CVD device.

In a composition range of the raw material gas supplied by the gas supply mechanism, a ratio of a concentration of O atoms to a total concentration of O atoms and H atoms is preferably 10 at % or more and 60 at % or less.

In the film forming device of the present invention described above, a carbon-based thin film can be formed also in such a composition range of the raw material gas.

Further, in the film forming device, the gas supply mechanism may supply an Ar gas together with the raw material gas into the vacuum container, and a ratio of a flow rate of the Ar gas to a total flow rate of all gases supplied into the vacuum container is preferably set to 50% or more and 90% or less.

By supplying an Ar gas together with the raw material gas, Ar, which is easy to ionize, can serve as a catalyst to promote decomposition of the raw material gas. Accordingly, the composition range of the raw material gas in which the carbon-based thin film can be formed can be set to a wider range. Such an effect is remarkable by setting the flow rate ratio of the Ar gas to 50% or more and 90% or less.

Further, in the film forming device, in an emission spectrum of the inductively coupled plasma, a ratio of a luminous intensity of C₂ radicals to a luminous intensity of Hα radicals is preferably 30% or more and 300% or less.

In the case where the ratio of the luminous intensity of C₂ radicals to the luminous intensity of Hα radicals is less than 30%, there is a possibility that etching becomes larger than film synthesis and nucleation does not occur. On the other hand, in the case where the ratio of the luminous intensity of C₂ radicals to the luminous intensity of Hα radicals is more than 300%, there is a possibility that the non-diamond components become large and graphite or a DLC film is formed.

A pressure in the vacuum container during film formation is preferably 7 Pa or more and 100 Pa or less.

In the case where the pressure in the vacuum container during film formation is less than 7 Pa, there is a possibility that the ion impact on the synthesized film increases, and a graphite film is formed. On the other hand, in the case where the pressure in the vacuum container during film formation is greater than 100 Pa, there is a possibility that plasma concentrates around the antenna and a carbon-based thin film cannot be synthesized.

As a specific example of the film forming device, the carbon-based thin film is a diamond film.

Further, a film forming method of the present invention includes the following. A raw material gas containing C, H, and O is supplied into a vacuum container in which a substrate is disposed. An inductively coupled plasma is generated in the vacuum container by passing a high-frequency current through an antenna that is disposed inside or outside the vacuum container and includes a conductor element and a capacitor element electrically connected in series with each other. A carbon-based thin film is formed on the substrate according to a plasma CVD method using the generated inductively coupled plasma.

With the film forming method configured as described above, the same action and effect as the film forming device of the present invention described above can be achieved.

### Effect of Invention

According to the present invention configured as described above, in the film forming device which forms a carbon-based thin film such as diamond according to the CVD method, the carbon-based thin film can be formed with a raw material gas having a wide composition range, and the film can be formed in a large area.

### BRIEF DESCRIPTION OF DRAWINGS

FIG. 1 is a view schematically showing a configuration of a film forming device according to an embodiment of the present invention.

FIG. 2 is a diagram showing a gas composition range of a raw material gas supplied in the film forming device and a first film forming method of the embodiment.

FIG. 3 is a diagram showing a relationship between a ratio of an Ar gas supplied and a luminous intensity ratio of C₂ radicals and Hα radicals in a plasma generated.

FIG. 4 is a diagram showing a gas composition range of a raw material gas supplied in a second film forming method.

FIG. 5 is a view showing a gas composition and a pressure during film formation of each Sample synthesized in Example 1.

FIG. 6 is a diagram showing Raman scattering spectra of each Sample synthesized in Example 1.

FIG. 7 is a view showing a gas composition and a pressure during film formation of each Sample synthesized in Example 2.

FIG. 8 is a diagram showing Raman scattering spectra of each Sample synthesized in Example 2.

FIG. 9 is a diagram showing a composition range of a raw material gas with which diamond can be synthesized in a conventional CVD method.

### DESCRIPTION OF EMBODIMENTS

Hereinafter, a film forming device and a film forming method according to an embodiment of the invention will be described with reference to the drawings.

### 1. Device Configuration

A film forming device 100 of the present embodiment is a plasma CVD device that performs formation of a carbon-based thin film on a substrate W according to a plasma CVD method using an inductively coupled plasma P. Herein, the carbon-based thin film is, for example, a diamond film, a diamond-like carbon (DLC) film, etc.

The substrate W of the present embodiment is a plate-shaped substrate composed of a material suitable for forming a carbon-based thin film. The substrate W may be composed of, for example, glass, plastic, silicon, metal such as iron, titanium, copper, and cemented carbide, another alloy material such as tool steel, or a material such as SiC, GaN, AlN, BN, and diamond, but is not limited thereto.

The substrate W has a rectangular shape, a circular shape, or the like in a plan view. A length of the substrate W may be, for example, 20 cm or more or 50 cm or more, but is not limited thereto. Further, the substrate W may be, for example, a substrate in which a plurality of small chip-shaped substrates of about 1 mm, 5 mm, or 10 mm are arranged with a same length or area. Further, the substrate W is not limited to a plate shape, and may also be a columnar shape, a perforated shape, or a porous shape. Further, it may have a complicated shape like a tool such as a drill or an end mill.

Further, the substrate W may be subjected to a surface treatment such as a so-called scratching treatment or a seeding treatment. For example, in the case where the substrate W is silicon, a scratching treatment or a seeding treatment may be performed to immerse in alcohol together with diamond fine particles and form roughness on the surface by an ultrasonic treatment. Further, for example, in the case where the substrate W is cemented carbide, after immersing in an acidic solution such as an aqueous nitric acid solution to remove Co in the substrate, or treating the surface of WC (tungsten carbide) particles with an alkaline solution such as diluted NaOH, the seeding treatment as described above may be performed.

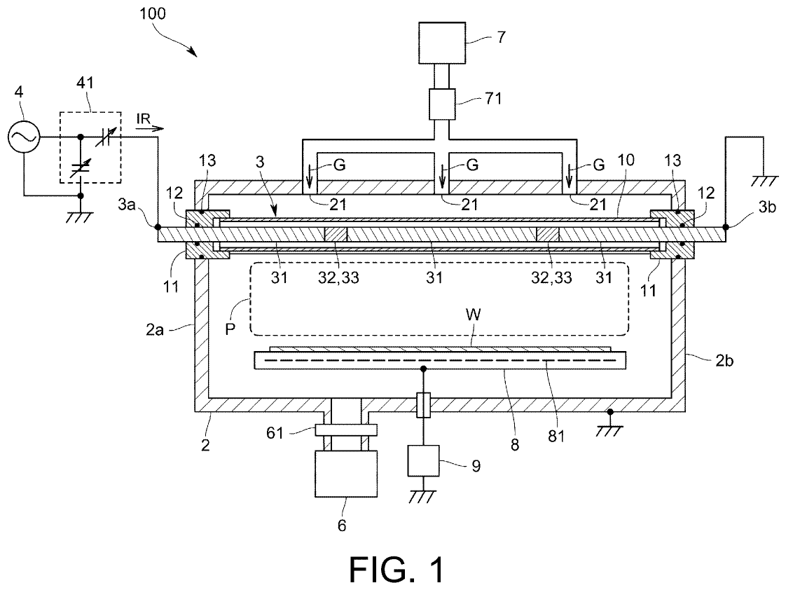

Specifically, as shown in FIG. 1, the film forming device 100 includes a vacuum container 2 that is vacuum-evacuated and into which a gas G is introduced, a gas supply mechanism 7 that supplies the gas G to the vacuum container 2, an antenna 3 in a straight-line shape disposed in the vacuum container 2, and a high-frequency power supply 4 that applies, to the antenna 3, a high frequency for generating an inductively coupled plasma P in the vacuum container 2. In the film forming device 100, a high-frequency current IR flows through the antenna 3 by applying a high frequency from the high-frequency power supply 4 to the antenna 3, and an induced electric field is generated in the vacuum container 2 to generate the inductively coupled plasma P.

The vacuum container 2 is a container made of metal such as SUS or aluminum, for example, and the inside of the vacuum container 2 is vacuum-evacuated by a vacuum-evacuating device 6. In this example, the vacuum container 2 is electrically grounded. The vacuum-evacuating device 6 includes a pressure regulator 61 such as a valve that regulates the pressure in the vacuum container 2. The pressure regulator 61 may be controlled to regulate the pressure in the vacuum container 2 during plasma generation, for example, regulating to a pressure of 7 Pa or more and 100 Pa or less.

The gas G such as a raw material gas is introduced into the vacuum container 2 via, for example, a flow rate regulator (not shown) and a plurality of gas inlets 21 disposed in a direction along the antenna 3.

Further, a substrate holder 8 that holds the substrate W is provided in the vacuum container 2, and a heater 81 that heats the substrate W is provided in the substrate holder 8. The substrate holder 8 may be electrically unconnected with the vacuum container 2. The film forming device 100 of this embodiment may have a function of regulating a potential with respect to the generated inductively coupled plasma in a range of, for example, +100 V to −100 V by applying a bias voltage from a bias power supply 9 to the substrate holder 8. The applied bias voltage is, for example, a negative direct current voltage, but is not limited thereto. With such a bias voltage, for example, an energy when positive ions in the plasma P are injected into the substrate W can be controlled to perform control on a crystallinity or the like of the film formed on the surface of the substrate W.

The gas supply mechanism 7 supplies the gas G such as the raw material gas into the vacuum container via the gas inlets 21. The gas supply mechanism 7 is configured to supply the gas G downward from the gas inlets 21 provided at an upper wall of the vacuum container 2. The gas supply mechanism 7 is configured to be capable of supplying a raw material gas containing at least C (carbon), H (hydrogen), and O (oxygen), and specifically, is configured to be capable of supplying a H₂ gas, a CH₄ gas, and a CO₂ gas as the raw material gas. The gas supply mechanism 7 may also be configured to supply any other gas as the raw material gas in addition to or in place of the H₂ gas, the CH₄ gas, and the CO₂ gas, as long as the gas supply mechanism 7 is configured to be capable of supplying a raw material gas containing C, H, and O into the vacuum container 2.

The gas supply mechanism 7 is configured to be capable of supplying the H₂ gas, the CH₄ gas, and the CO₂ gas respectively at any flow rates. The gas supply mechanism 7 of the present embodiment is configured to be capable of regulating the flow rate of each gas and supplying the gas such that a ratio (O/(O+H)) of a concentration of O atoms to a total concentration of O atoms and H atoms contained in the raw material gas containing the H₂ gas, the CH₄ gas, and the CO₂ gas is, for example, 10 at % or more and 60 at % or less.

Further, the gas supply mechanism 7 is configured to be capable of supplying a catalyst gas into the vacuum container 2 at any flow rate together with the raw material gas. The catalyst gas functions as a catalyst during plasma generation and promotes decomposition of the raw material gas. Specifically, the gas supply mechanism 7 is configured to be capable of supplying the catalyst gas such that a ratio to a total flow rate of all gases supplied into the vacuum container 2 (herein, a total flow rate of the raw material gas and the catalyst gas) is, for example, 50% or more and 90% or less, and preferably 75% or more and 90% or less. Specifically, examples of the catalyst gas include rare gases such as an Ar gas, a He gas, and a Ne gas.

The antenna 3 is disposed above the substrate W in the vacuum container 2 along the surface of the substrate W. In the present embodiment, a plurality of antennas 3 in a straight-line shape are disposed in parallel along the substrate W (e.g., substantially parallel to the surface of the substrate W). In this manner, the plasma P with good uniformity can be generated in a wider range, and thus, treatment of a larger substrate W can be handled.

The quantity of the antenna 3 is not limited to a plurality and may also be one only. In the case where a plurality of antennas 3 are included, the quantity of the antennas 3 is preferably an even number (e.g., two, four, six, etc.). Further, in the case where a plurality of antennas 3 are included, to avoid radio wave interference, an interval between the antennas 3 is preferably 5 cm or more, more preferably 10 cm or more, and still more preferably 15 cm or more. On the other hand, to form a uniform carbon-based thin film, the interval between the antennas 3 is preferably 25 cm or less. Further, in the case where a plurality of antennas 3 are included, preferably, the plurality of antennas 3 are disposed to be arranged parallel to each other and on a same plane, and are disposed such that a plane surrounded by the antennas 3 on both ends has a square or rectangular shape (preferably, one side is 40 cm or more). More preferably, one side is 50 cm or more, more preferably one side is 70 cm or more, and more preferably one side is 100 cm or more.

As shown in FIG. 1, vicinities of both end parts of the antenna 3 respectively penetrate a pair of sidewalls 2a and 2b of the vacuum container 2 that face each other. Insulating members 11 are respectively provided at portions that allow the both end parts of the antenna 3 to penetrate to outside the vacuum container 2. The both end parts of the antenna 3 penetrate the insulating members 11, and the penetrated parts are vacuum-sealed by, for example, a packing 12. The antenna 3 is supported via the insulating members 11, in a state of being electrically insulated from the sidewalls 2a and 2b of the vacuum container 2 facing each other. A space between each insulating member 11 and the vacuum container 2 is also vacuum-sealed by, for example, a packing 13. A material of the insulating member 11 is, for example, a ceramic such as alumina, quartz, or an engineering plastic such as polyphenylene sulfide (PPS) and polyether ether ketone (PEEK).

Further, the antenna 3 is a so-called LC antenna including an L part serving as an inductor and a C part serving as a capacitor. Specifically, the antenna 3 includes at least two conductor elements 31 (hereinafter referred to as “metal pipes 31”) made of metal having a tubular shape, an insulating element 32 (hereinafter referred to as an “insulating pipe 32”) in a tubular shape provided between the metal pipes 31 adjacent to each other to insulate the metal pipes 31, and a capacitor 33 which is a capacitor element that is provided between the metal pipes 31 adjacent to each other and is electrically connected thereto in series. The conductor element 31 functions as the L part, and the capacitor 33 functions as the C part.

In the present embodiment, the quantity of the metal pipes 31 is three, and the quantities of the insulating pipes 32 and the capacitors 33 are respectively two. The antenna 3 may also have a configuration including four or more metal pipes 31, and in that case, the quantities of the insulating pipes 32 and the capacitors 33 are respectively one less than the quantity of the metal pipes 31.

The material of the metal pipe 31 is, for example, copper, aluminum, an alloy thereof, stainless steel, etc., but is not limited thereto. The antenna 3 may be hollowed and a coolant such as cooling water may be flowed therein to cool the antenna 3.

The insulating pipe 32 of the present embodiment is formed of one member, but is not limited thereto. A material of the insulating pipe 32 is, for example, alumina, fluororesin, polyethylene (PE), engineering plastics (e.g., polyphenylene sulfide (PPS) and polyether ether ketone (PEEK)), etc.

Furthermore, in the antenna 3, a portion located in the vacuum container 2 is covered by an insulating cover (antenna protection tube) 10 in a straight-tube shape. Both end parts of the insulating cover 10 are supported by the insulating members 11. It is possible not to seal between the both end parts of the insulating cover 10 and the insulating members 11. This is because even if the gas G enters the space in the insulating cover 10, since the space is small and an electron movement distance is short, the plasma P is generally not generated in the space. A material of the insulating cover 10 is, for example, quartz, alumina, fluororesin, silicon nitride, silicon carbide, silicon, etc.

By providing the insulating cover 10, since charged particles in the plasma P can be suppressed from being injected into the metal pipe 31 constituting the antenna 3, it is possible to suppress an increase in a plasma potential caused by the injection of charged particles (mainly electrons) into the metal pipe 31, and it is possible to suppress sputtering of the metal pipe 31 by charged particles (mainly ions) and thus suppress occurrence of metal contamination in the plasma P and the substrate W.

A length of the antenna 3 is, for example, preferably 20 cm or more, more preferably 50 cm or more, and still more preferably 100 cm or more. On the other hand, from the viewpoint of ensuring a strength of the insulating pipe 32, the length of the antenna 3 is preferably 1000 cm or less, and more preferably 500 cm or less.

As shown in FIG. 1, the antenna 3 includes a power feed end part 3a to which a high-frequency power is fed in an antenna direction (longitudinal direction X), and a grounded end part 3b which is grounded. Specifically, at both end parts of each antenna 3 in the longitudinal direction X, a portion extending outward from one sidewall 2a or 2b serves as the power feed end part 3a, and a portion extending outward from the other sidewall 2a or 2b serves as the grounded end part 3b.

Herein, a high frequency is applied from the high-frequency power supply 4 via a matching device 41 to the power feed end part 3a of each antenna 3. The frequency of the high frequency is 400 kHz or more and 100 MHz or less, and is generally, for example, 13.56 MHz, but is not limited thereto. For example, the frequency may be 27.12 MHz, 40.68 MHz, 60 MHz, etc.

### 2. Film Forming Method

Next, a film forming method of a carbon-based thin film using the film forming device 100 described above will be described. Hereinafter, a first film forming method and a second film forming method in which composition ratios of the supplied raw material gas are different from each other will be described. According to the film forming device 100 described above, a carbon-based thin film such as diamond can be formed by any of the film forming methods.

### First Film Forming Method

First, a substrate W is set on the substrate holder 8 in the vacuum container 2 of the film forming device 100, and the vacuum container 2 is vacuum-evacuated by the vacuum-evacuating device 6. Preferably, the substrate W is heated by the heater 81, and the temperature of the substrate W is set to 100° C. or more and 1200° C. or less. A range of the temperature of the substrate W may be changed depending on a particle size or crystallinity of the diamond to be synthesized. In the first film forming method, for example, in the case of synthesizing a carbon-based thin film in which diamond microcrystals are present in a DLC film, the temperature of the substrate W is preferably set to 100° C. or more and 400° C. or less. In the case of synthesizing a carbon-based thin film containing diamond having a particle size of 200 nm or less, the temperature of the substrate W is preferably set to 200° C. or more and less than 500° C. In the case of synthesizing a carbon-based thin film containing diamond having a particle size of 200 nm or more and 1000 nm or less, the temperature of the substrate W is preferably set to 200° C. or more and less than 500° C. In the case of synthesizing a carbon-based thin film containing diamond having a particle size of 1000 nm or more, the temperature of the substrate W is preferably set to 700° C. or more and 1200° C. or less.

### Supply of Raw Material Gas

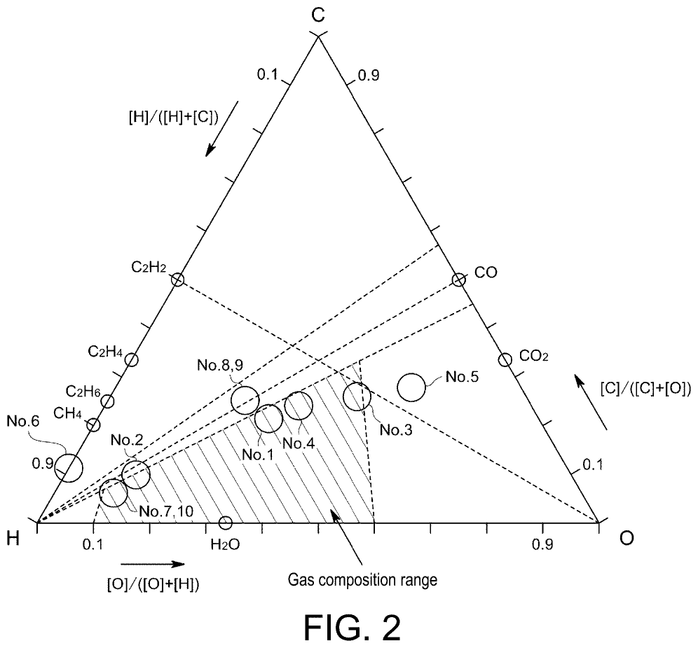

Next, a H₂ gas, a CH₄ gas, and a CO₂ gas serving as the raw material gas are supplied into the vacuum container 2 at predetermined flow rates by the gas supply mechanism 7. In the film forming method of the present embodiment, each flow rate of the H₂ gas, the CH₄ gas, and the CO₂ gas is regulated such that atomic number ratios of O atoms, C atoms, and H atoms in the raw material gas fall within a range of oblique lines shown in a composition ternary plot (C—H—O diagram) of FIG. 2. The atomic number ratios of each atom will be described below.

### Atomic Number Ratio Between Oxygen and Hydrogen

Each flow rate of the H₂ gas, the CH₄ gas, and the CO₂ gas is controlled and supplied such that a ratio (O/(O+H)) of a concentration of O atoms to a total concentration of O atoms and H atoms contained in the supplied raw material gas is preferably 10 at % or more and 60 at % or less, and more preferably 30 at % or more and 50 at % or less.

### Atomic Number Ratio Between Oxygen and Carbon

Each flow rate of the H₂ gas, the CH₄ gas, and the CO₂ gas is controlled and supplied such that a ratio (C/(O+C)) of a concentration of C atoms to a total concentration of O atoms and C atoms contained in the supplied raw material gas is preferably 30 at % or more and 45 at % or less, and more preferably 35 at % or more and 45 at % or less.

### Atomic Number Ratio Between Carbon and Hydrogen

Further, each flow rate of the H₂ gas, the CH₄ gas, and the CO₂ gas is controlled and supplied such that a ratio (H/(C+H)) of a concentration of H atoms to a total concentration of C atoms and H atoms contained in the supplied raw material gas is preferably 40 at % or more and 90 at % or less, and more preferably 50 at % or more and 80 at % or less.

### Supply of Catalyst Gas

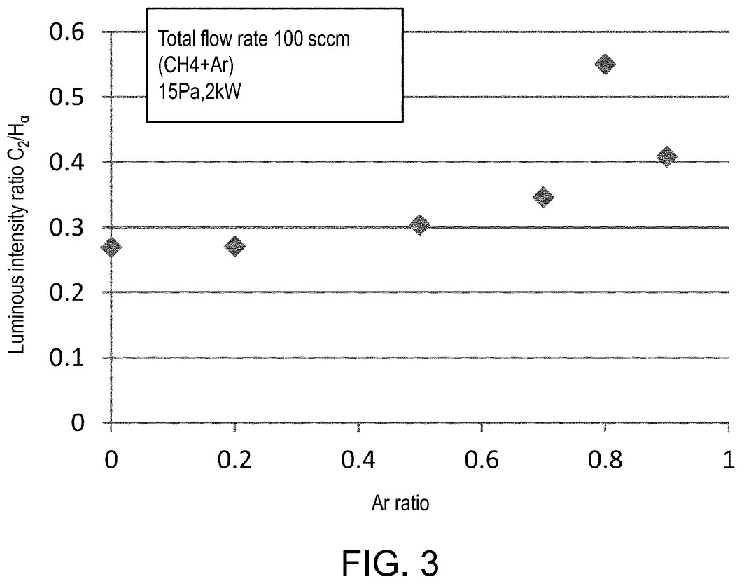

Furthermore, a catalyst gas such as an Ar gas is supplied into the vacuum container together with the raw material gas by the gas supply mechanism 7. A flow rate of the supplied catalyst gas is set such that a ratio to a total flow rate of all gases supplied to the vacuum container 2 is preferably 50% or more and 90% or less, and more preferably 75% or more and 90% or less. By setting the flow rate of the supplied catalyst gas within such a range, an energy can be transferred, for example, from Ar, which is easy to ionize, to CH₄ during film formation, and a large number of C₂ radicals, which easily generate diamond, can be generated. Accordingly, as shown in FIG. 3, in an emission spectrum of the inductively coupled plasma generated, a ratio of a luminous intensity of C₂ radicals to a luminous intensity of Hα radicals can be set to 30% or more and 300% or less, and more preferably 90% or more and 250% or less.

### Pressure in Vacuum Container

Then, a pressure in the vacuum container 2 is regulated by the pressure regulator 61 to be 7 Pa or more and 100 Pa or less, more preferably 10 Pa or more and 50 Pa or less, while the raw material gas and the catalyst gas are introduced by the gas supply mechanism 7.

### Generation of Plasma and Film Formation of Carbon-Based Thin Film

Then, with the flow rates of the raw material gas and the catalyst gas regulated and the pressure in the vacuum container 2 regulated as described above, a high-frequency power is supplied to the antenna 3 from the high-frequency power supply 4. Accordingly, an induced electric field is generated in the vacuum container 2 to generate an inductively coupled plasma P and form a carbon-based thin film on the substrate W. A frequency of the high-frequency power is 400 kHz or more and 100 MHz or less, and is preferably 13.56 MHz, for example. Further, a power density of the supplied high-frequency power is preferably 0.1 W/cm² or more, more preferably 0.5 W/cm² or more, and still more preferably 1 W/cm² or more. Further, the power density is preferably 1000 W/cm² or less, more preferably 100 W/cm² or less, and still more preferably 50 W/cm² or less.

### Second Film Forming Method

Next, a second film forming method in which the gas composition ratio of the supplied raw material gas is different from the first film forming method will be described. First, a substrate W is set on the substrate holder 8 in the vacuum container 2 of the film forming device 100, and the vacuum container 2 is vacuum-evacuated by the vacuum-evacuating device 6. Preferably, the substrate W is heated by the heater 81, and the temperature of the substrate W is set to 100° C. or more and 1200° C. or less. The range of the temperature of the substrate W may be changed depending on the particle size or crystallinity of the diamond to be synthesized. In the second film forming method, in the case of synthesizing a carbon-based thin film containing diamond having a particle size of 50 nm or less, preferably, the supplied raw material gas is hydrogen-rich, and the temperature of the substrate W is set to 500° C. or more and 1200° C. or less. In the case of synthesizing a carbon-based thin film containing diamond having a particle size of 10 nm or less, preferably, the supplied raw material gas is oxygen-rich, and the temperature of the substrate W is set to 800° C. or less.

### Supply of Raw Material Gas

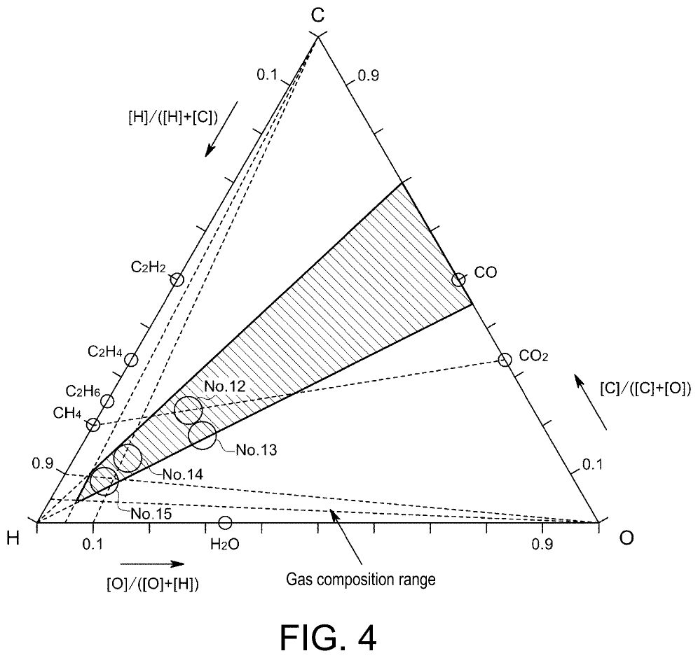

Next, a H₂ gas, a CH₄ gas, and a CO₂ gas serving as the raw material gas are supplied into the vacuum container 2 at predetermined flow rates by the gas supply mechanism 7. In the film forming method of the present embodiment, each flow rate of the H₂ gas, the CH₄ gas, and the CO₂ gas is regulated such that atomic number ratios of O atoms, C atoms, and H atoms in the raw material gas fall within a range of oblique lines shown in a composition ternary plot (C—H—O diagram) of FIG. 4. The atomic number ratios of each atom will be described below.

### Atomic Number Ratio Between Oxygen and Hydrogen

Each flow rate of the H₂ gas, the CH₄ gas, and the CO₂ gas is controlled and supplied such that a ratio (O/(O+H)) of a concentration of O atoms to a total concentration of O atoms and H atoms contained in the supplied raw material gas is preferably 5 at % or more and 45 at % or less, and more preferably 5 at % or more and 10 at % or less.

### Atomic Number Ratio Between Oxygen and Carbon

Each flow rate of the H₂ gas, the CH₄ gas, and the CO₂ gas is controlled and supplied such that a ratio (C/(O+C)) of a concentration of C atoms to a total concentration of O atoms and C atoms contained in the supplied raw material gas is preferably 45 at % or more and 70 at % or less.

### Atomic Number Ratio Between Carbon and Hydrogen

Further, each flow rate of the H₂ gas, the CH₄ gas, and the CO₂ gas is controlled and supplied such that a ratio (H/(C+H)) of a concentration of H atoms to a total concentration of C atoms and H atoms contained in the supplied raw material gas is preferably 60 at % or more and 95 at % or less, and more preferably 90 at % or more and 95 at % or less.

### Supply of Catalyst Gas

Furthermore, a catalyst gas such as an Ar gas is supplied into the vacuum container together with the raw material gas by the gas supply mechanism 7. A flow rate of the supplied catalyst gas is set such that a ratio to a total flow rate of all gases supplied to the vacuum container 2 is preferably 50% or more and 95% or less, and more preferably 70% or more and 90% or less. By setting the flow rate of the supplied catalyst gas within such a range, in an emission spectrum of the inductively coupled plasma generated, a ratio of a luminous intensity of C₂ radicals to a luminous intensity of Hα radicals can be set to 30% or more and 300% or less, and more preferably 90% or more and 250% or less.

### Pressure in Vacuum Container

Then, a pressure in the vacuum container 2 is regulated by the pressure regulator 61 to be 7 Pa or more and 100 Pa or less, more preferably 10 Pa or more and 50 Pa or less, while the raw material gas and the catalyst gas are introduced by the gas supply mechanism 7.

### Generation of Plasma and Film Formation of Carbon-Based Thin Film

Then, with the flow rates of the raw material gas and the catalyst gas regulated and the pressure in the vacuum container 2 regulated as described above, a high-frequency power is supplied to the antenna 3 from the high-frequency power supply 4. Accordingly, an induced electric field is generated in the vacuum container 2 to generate an inductively coupled plasma P and form a carbon-based thin film on the substrate W. A frequency of the high-frequency power is 400 kHz or more and 100 MHz or less, and is preferably 13.56 MHz, for example. Further, a power density of the supplied high-frequency power is preferably 0.1 W/cm² or more, more preferably 0.5 W/cm² or more, and still more preferably 1 W/cm² or more. Further, the power density is preferably 1000 W/cm² or less, more preferably 100 W/cm² or less, and still more preferably 50 W/cm² or less.

### 3. Effect of Present Embodiment

According to the film forming device 100 and the film forming method of the present embodiment configured in this manner, by using an inductively coupled plasma P generated by an induced electric field of a high frequency, it becomes possible to decompose CO₂ or the like, which is a molecule with a high binding energy contained in the raw material gas, over a wide range, and generation of oxygen-containing radicals can be promoted. Furthermore, since the inductively coupled plasma is generated by the antenna 3, long-time activation can be performed even if the raw material gas has a gas composition containing a large amount of oxygen. Accordingly, a carbon-based thin film such as diamond can be formed with a raw material gas having a wide composition range that cannot be realized by a method using a conventional CVD device, and a carbon-based thin film having a large area can be formed compared to a conventional plasma CVD device.

Further, by introducing an Ar gas as the catalyst gas, generation of C₂ radicals can also be promoted. By forming a film on the substrate W with the C₂ radicals and the like and removing a non-diamond component with oxygen-containing radicals and hydrogen radicals, a carbon-based thin film such as diamond can be easily formed on the substrate W.

Further, according to the film forming device 100 and the film forming method of the present embodiment described above, in the case where a Raman spectroscopic analysis with 325 nm excitation is performed, a diamond film can be formed, in which a peak intensity of the diamond in the vicinity of 1333 cm⁻¹ is more than 20%, preferably 100% or more, and more preferably 1000% or more, of a peak intensity of a G-band in the vicinity of 1550 cm⁻¹.

The film forming device 100 of the present invention is not limited to the above-described embodiment.

For example, in the film forming device 100 of the above embodiment, the antenna 3 generating the inductively coupled plasma is disposed in the vacuum container 2, but the present invention is not limited thereto. A film forming device 100 of another embodiment may have a structure in which the antenna 3 is disposed outside the vacuum container 2.

The present invention is not limited to the above-described embodiments, and various modifications may be made without departing from the spirit and scope of the present invention. For example, it is understood by those skilled in the art that the above-described exemplary embodiments are specific examples of the following aspects.

(Aspect 1) A film forming device including: a vacuum container in which a substrate is disposed; an antenna that generates an inductively coupled plasma in the vacuum container and includes a conductor element and a capacitor element electrically connected in series with each other; a high-frequency power supply that supplies a high-frequency current to the antenna; and a gas supply mechanism that supplies a raw material gas containing C, H, and O into the vacuum container, where a carbon-based thin film is formed on the substrate in the vacuum container according to a plasma CVD method using the inductively coupled plasma that is generated in the vacuum container by passing the high-frequency current through the antenna.

(Aspect 2) The film forming device according to Aspect 1, where in a composition of the raw material gas supplied by the gas supply mechanism, a ratio of a concentration of O atoms to a total concentration of O atoms and H atoms is 10 at % or more and 60 at % or less.

(Aspect 3) The film forming device according to Aspect 1 or 2, where the gas supply mechanism supplies a catalyst gas together with the raw material gas into the vacuum container, and a ratio of a flow rate of the catalyst gas to a total flow rate of all gases supplied into the vacuum container is set to 50% or more and 90% or less.

(Aspect 4) The film forming device according to Aspect 3, where the catalyst gas is an Ar gas.

(Aspect 5) The film forming device according to any one of Aspects 1 to 4, where in an emission spectrum of the inductively coupled plasma, a ratio of a luminous intensity of C₂ radicals to a luminous intensity of Hα radicals is 30% or more and 300% or less.

(Aspect 6) The film forming device according to any one of Aspects 1 to 5, where a pressure in the vacuum container during film formation is 7 Pa or more and 100 Pa or less.

(Aspect 7) The film forming device according to any one of Aspects 1 to 6, where the antenna has a straight-line shape and has a length of 20 cm or more.

(Aspect 8) The film forming device according to any one of Aspects 1 to 5, where the carbon-based thin film is a diamond film.

(Aspect 9) The film forming device according to any one of Aspects 1 to 8, where in a Raman spectroscopic analysis with 325 nm excitation, a peak intensity of diamond of the diamond film in the vicinity of 1333 cm⁻¹ is more than 20% of a peak intensity of a G band in the vicinity of 1550 cm⁻¹.

(Aspect 10) A film forming method including: supplying a raw material gas containing C, H, and O into a vacuum container in which a substrate is disposed; generating an inductively coupled plasma in the vacuum container by passing a high-frequency current through an antenna that is disposed inside or outside the vacuum container and includes a conductor element and a capacitor element electrically connected in series with each other; and forming a carbon-based thin film on the substrate according to a plasma CVD method using the generated inductively coupled plasma.

(Aspect 11) The film forming method according to Aspect 10, where the carbon-based thin film is a diamond film, and in a Raman spectroscopic analysis with 325 nm excitation, a peak intensity of diamond of the diamond film in the vicinity of 1333 cm⁻¹ is more than 20% of a peak intensity of a G-band in the vicinity of 1550 cm⁻¹.

### 4. EXAMPLES

The present invention will be described more specifically below with reference to Examples. The present invention is not limited by the following Examples, and may be implemented with modifications within the scope that may be adapted to the gist described below, and all of these are included in the technical scope of the present invention.

### Example 1

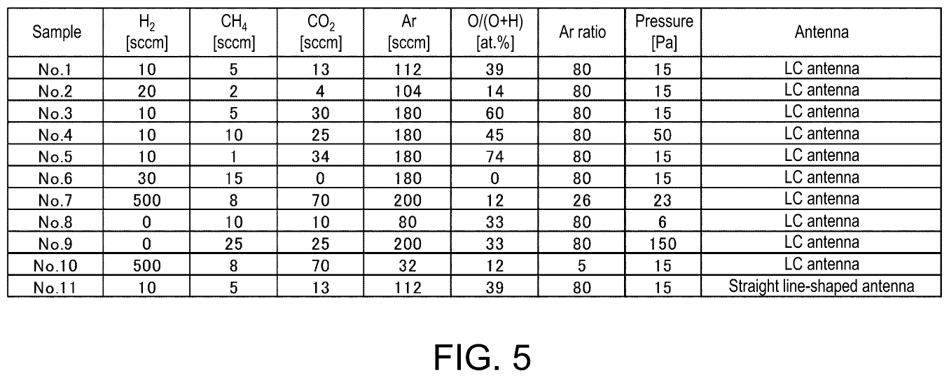

In Example 1, according to a plasma CVD method using the film forming device 100 described above, films of a plurality of Samples (No. 1 to No. 10) were formed on substrates by changing the composition of the raw material gas, the pressure of the vacuum container 2, and the flow rate ratio of the Ar gas. Further, Sample No. 11 was formed on a substrate using a film forming device with an antenna in a simple straight-line shape that is not an LC antenna (i.e., not including a capacitor part). The flow rate of the raw material gas, the composition of the raw material gas, the flow rate ratio of the Ar gas, and the pressure in the vacuum container 2 during film formation of each Sample are as shown in FIG. 5. Other film formation conditions are as follows.
Frequency of supplied high-frequency power: 13.56 MHz
Power density of supplied high-frequency power: 1.4 W/cm²
Substrate temperature: 500° C.

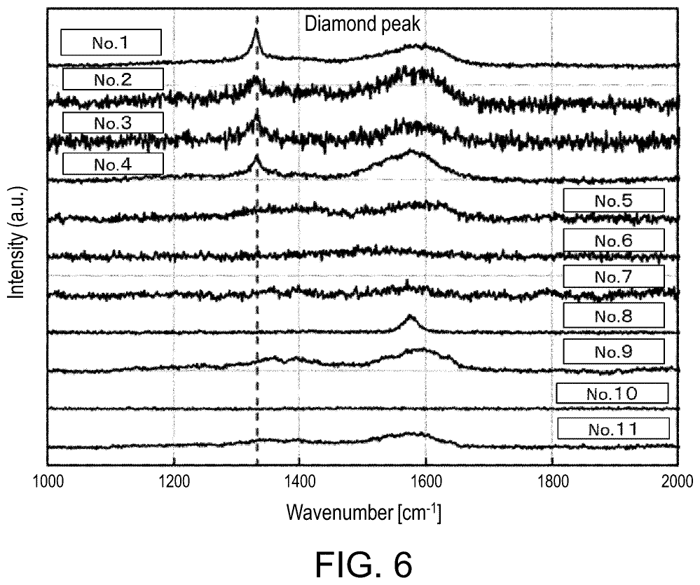

Then, the crystallinity of the formed film of each Sample was evaluated according to a laser Raman spectroscopy (325 nm excitation). The Raman scattering spectra obtained for each Sample are shown in FIG. 6. As shown in FIG. 6, an optical phonon peak of diamond was observed in the vicinity of the wavelength of 1333 cm⁻¹ and it could be confirmed that a film of diamond can be formed in Samples of No. 1 to No. 4, in which the LC antenna was used, and in the raw material gas, the ratio of the concentration of O atoms to the total concentration of O atoms and H atoms was 10 at % or more and 60 at % or less, the flow rate ratio of the Ar gas in all gases was 50% or more and 90% or less, and the pressure in the vacuum container 2 was set to 7 Pa or more and 100 Pa or less.

### Example 2

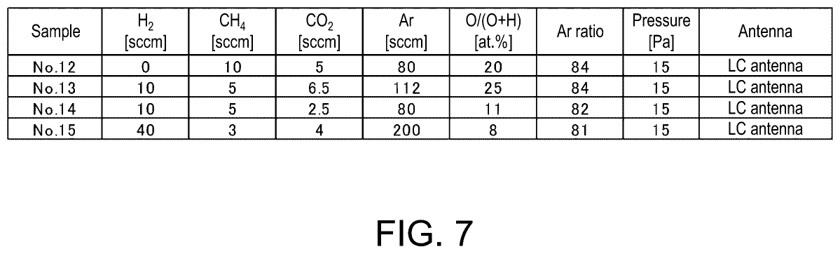

In Example 2, according to a plasma CVD method using the film forming device 100 described above, films of a plurality of Samples (No. 12 to No. 15) were formed on substrates by changing the composition of the raw material gas, the pressure of the vacuum container 2, and the flow rate ratio of the Ar gas. The flow rate of the raw material gas, the composition of the raw material gas, the flow rate ratio of the Ar gas, and the pressure in the vacuum container 2 during film formation of each Sample are as shown in FIG. 7. Other film formation conditions are as follows.
Frequency of supplied high-frequency power: 13.56 MHz
Power density of supplied high-frequency power: 1.4 W/cm²
Substrate temperature: 500° C.

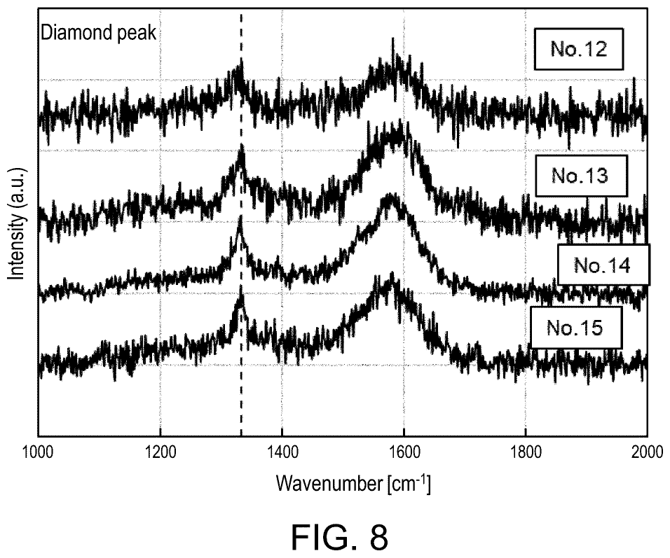

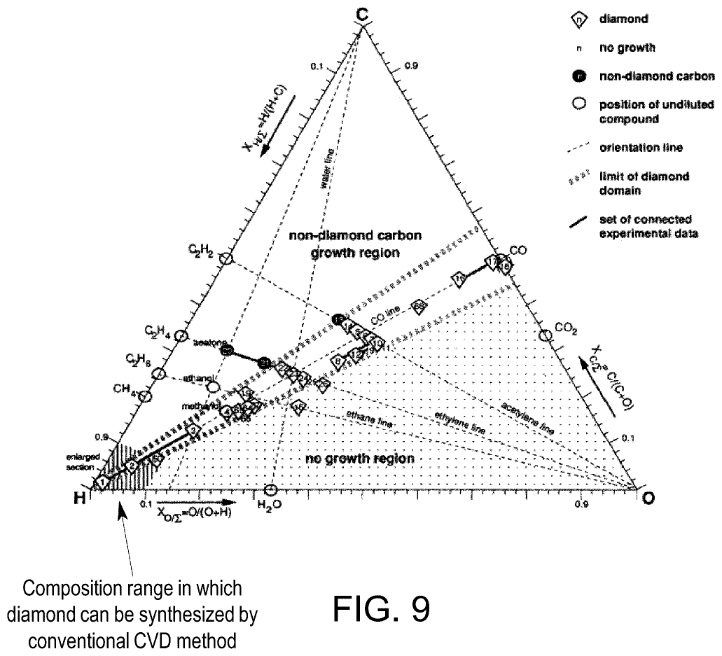

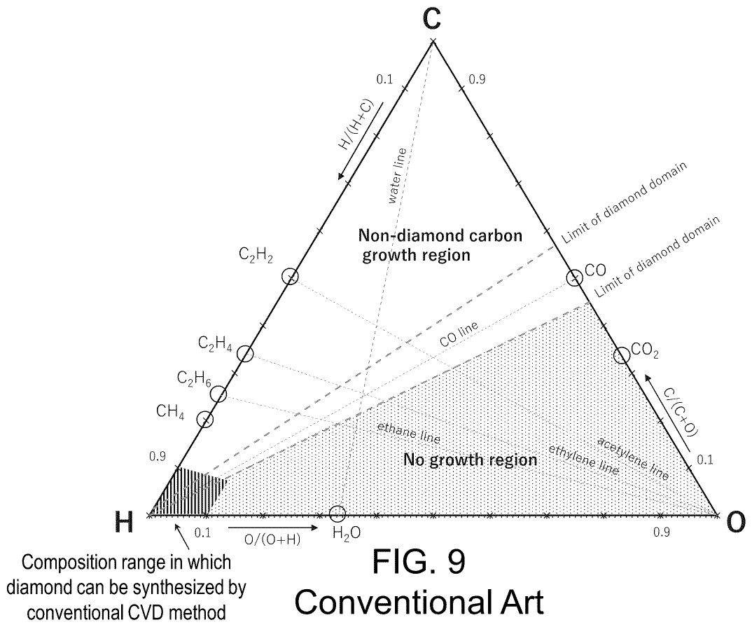

Then, the crystallinity of the formed film of each Sample was evaluated according to a laser Raman spectroscopy (325 nm excitation). The Raman scattering spectra obtained for each Sample are shown in FIG. 8. As shown in FIG. 8, an optical phonon peak of diamond was observed in the vicinity of the wavelength of 1333 cm⁻¹ and it could be confirmed that a film of diamond can be formed in Samples of No. 12 to No. 15, in which the LC antenna was used, and in the raw material gas, the ratio of the concentration of O atoms to the total concentration of O atoms and H atoms was 5 at % or more and 45 at % or less, the ratio of the concentration of C atoms to the total concentration of O atoms and C atoms was 45 at % or more and 70 at % or less, the ratio of the concentration of H atoms to the total concentration of C atoms and H atoms was 60 at % or more and 95 at % or less, the flow rate ratio of the Ar gas in all gases was 50% or more and 95% or less, and the pressure in the vacuum container 2 was set to 7 Pa or more and 100 Pa or less (specifically, 15 Pa).

### INDUSTRIAL APPLICABILITY

According to the present invention, in the film forming device forming a carbon-based thin film such as diamond according to the CVD method, it becomes possible to form a carbon-based thin film with a raw material gas having a wide composition range, and film formation in a large area becomes possible.

### REFERENCE SIGNS LIST

100 Plasma CVD device
2 Vacuum container
3 Antenna
7 Gas supply mechanism
10 W Substrate
P Plasma

1. A film forming device comprising:
a vacuum container in which a substrate is disposed;
an antenna that generates an inductively coupled plasma in the vacuum container and comprises a conductor element and a capacitor element electrically connected in series with each other;
a high-frequency power supply that supplies a high-frequency current to the antenna; and
a gas supply mechanism that supplies a raw material gas containing C, H, and O into the vacuum container, wherein
a carbon-based thin film is formed on the substrate in the vacuum container according to a plasma CVD method using the inductively coupled plasma that is generated in the vacuum container by passing the high-frequency current through the antenna.

2. The film forming device according to claim 1, wherein in a composition of the raw material gas supplied by the gas supply mechanism, a ratio of a concentration of O atoms to a total concentration of O atoms and H atoms is 10 at % or more and 60 at % or less.

3. The film forming device according to claim 1, wherein the gas supply mechanism supplies a catalyst gas together with the raw material gas into the vacuum container, and a ratio of a flow rate of the catalyst gas to a total flow rate of all gases supplied into the vacuum container is set to 50% or more and 90% or less.

4. The film forming device according to claim 3, wherein the catalyst gas is an Ar gas.

5. The film forming device according to claim 1, wherein in an emission spectrum of the inductively coupled plasma, a ratio of a luminous intensity of C₂ radicals to a luminous intensity of Hα radicals is 30% or more and 300% or less.

6. The film forming device according to claim 1, wherein a pressure in the vacuum container during film formation is 7 Pa or more and 100 Pa or less.

7. The film forming device according to claim 1, wherein the antenna has a straight-line shape and has a length of 20 cm or more.

8. The film forming device according to claim 1, wherein the carbon-based thin film is a diamond film.

9. The film forming device according to claim 8, wherein in a Raman spectroscopic analysis with 325 nm excitation, a peak intensity of diamond of the diamond film in the vicinity of 1333 cm⁻¹ is more than 20% of a peak intensity of a G band in the vicinity of 1550 cm⁻¹.

10. A film forming method comprising:
supplying a raw material gas containing C, H, and O into a vacuum container in which a substrate is disposed;
generating an inductively coupled plasma in the vacuum container by passing a high-frequency current through an antenna that is disposed inside or outside the vacuum container and comprises a conductor element and a capacitor element electrically connected in series with each other; and
forming a carbon-based thin film on the substrate according to a plasma CVD method using the generated inductively coupled plasma.

11. The film forming method according to claim 10, wherein the carbon-based thin film is a diamond film, and in a Raman spectroscopic analysis with 325 nm excitation, a peak intensity of diamond of the diamond film in the vicinity of 1333 cm⁻¹ is more than 20% of a peak intensity of a G-band in the vicinity of 1550 cm⁻¹.
